(19) United States
(12) Patent Application Publication
(10) Pub. No.: US 2025/0355417 A1
(43) Pub. Date: Nov. 20, 2025

(54) DATA ENCODING DEVICE AND NON-TRANSITORY COMPUTER-READABLE MEDIUM STORING A DATA ENCODING PROGRAM

(71) Applicant: FANUC CORPORATION, Yamanashi (JP)

(72) Inventor: Daijirou KOGA, Yamanashi (JP)

(73) Assignee: FANUC CORPORATION, Yamanashi (JP)

(21) Appl. No.: 18/872,020

(22) PCT Filed: Jun. 24, 2022
(86) PCT No.: PCT/JP2022/025415

§ 371 Date: Dec. 5, 2024

(51) Int. Cl. G05B 19/404; G05B 19/408

(52) U.S. Cl. CPC G05B 19/404; G05B 19/408

(57) ABSTRACT

Provided is an encoding technology with which it is possible to encode and compress shaft-dependent data that is dependent on coordinate values of each shaft of an industrial machine. A data encoding device 1 comprising a model approximation encoding unit 11 that, on the basis of some shaft-dependent data that is dependent on coordinate values of each shaft of an industrial machine and a linear combination model that approximates the shaft-dependent data as a linear combination of shaft data pertaining to the industrial machine, generates encoded shaft-dependent data in which the shaft-dependent data is encoded.

### TECHNICAL FIELD

The present disclosure relates to a data encoding device and a data encoding program.

### BACKGROUND ART

Conventionally, industrial machines such as a machine tool and a robot each cause a predetermined control point to move to a predetermined position in accordance with a command value. However, since such industrial machines are subject to errors, the position of the control point often does not conform to the command value. In order to resolve such a decrease in positioning accuracy which would lead to a decrease in machining accuracy, a technique has been proposed which compensates for an error so that the position of a control point conforms to a command value (for example, refer to Patent Document 1). With this technique, by inputting the error amount measured in advance to a control device, the error is compensated based on the compensation amount corresponding to the error amount.

### CITATION LIST

### Patent Document

Patent Document 1: Japanese Unexamined Patent Application, Publication No. 2011-209897

### DISCLOSURE OF THE INVENTION

### Problems to be Solved by the Invention

However, upon compensating for the error, as the number of input points of the error amount inputted to the control device increases, the error can be compensated with higher accuracy. However, since there is an upper limit to the inputtable data size, there is a problem in that the accuracy of error compensation cannot be improved beyond the upper limit of the inputtable data size.

Therefore, it is conceivable to compress the data of the error amount and input the compressed data to the control device. Examples of a technique for compressing data include a data encoding technique, and for example, an entropy encoding technique such as Huffman coding is known. The entropy encoding technique compresses data by utilizing bias in the appearance frequency of values on the data, i.e., the smallness of information entropy.

However, the axis-dependent data depending on the coordinate values of each axis of an industrial machine such as the above-described error amount may have a white noise-like property in which the appearance frequency is uniform as a whole. In this case, since the above-described smallness of information entropy cannot be used, it is difficult to compress data by the entropy encoding.

The present disclosure has been made in view of the above, and an object of the present disclosure is to provide a data encoding technique capable of encoding and compressing axis-dependent data which depends on the coordinate values of each axis of an industrial machine.

### Means for Solving the Problems

An aspect of the present disclosure is directed to a data encoding device that encodes data, including: a model approximation encoder that generates, based on a portion of axis-dependent data depending on coordinate values of each axis of an industrial machine and a linear combination model that approximates the axis-dependent data as a linear combination of data of each axis of the industrial machine, encoded axis-dependent data obtained by encoding the axis-dependent data.

Another aspect of the present disclosure is directed to a data encoding program for encoding data, the program causing a computer to execute a step of generating, based on a portion of axis-dependent data depending on coordinate values of each axis of an industrial machine and a linear combination model that approximates the axis-dependent data as a linear combination of data of each axis of the industrial machine, encoded axis-dependent data obtained by encoding the axis-dependent data.

### Effects of the Invention

According to the present disclosure, it is possible to provide a data encoding technique capable of encoding and compressing axis-dependent data which depends on the coordinate values of each axis of an industrial machine.

### BRIEF DESCRIPTION OF THE DRAWINGS

FIG. 1 is a diagram showing the configuration of a data encoding device according to a first embodiment;

FIG. 2 is a diagram showing an example of a text file including only specific characters;

FIG. 3 is a diagram showing an example of data in which the appearance frequency of each value is represented by a specific distribution;

FIG. 4 is a diagram showing data in which the appearance frequency of each value is uniform;

FIG. 5 is a diagram showing each axis error of an X-axis error;

FIG. 6 is a diagram showing each axis error of the Y axis;

FIG. 7 is a diagram showing error amounts at coordinate values (X₂, Y₁);

FIG. 8 is a diagram showing error amounts which cannot be expressed with a linear combination of each axis error;

FIG. 9 is a partially enlarged view of FIG. 8;

FIG. 10 is a diagram showing a bitmap image in which an error map is visualized;

FIG. 11 is a diagram showing an example of axis-dependent data;

FIG. 12 is a diagram showing a linear combination model approximating the axis-dependent data of FIG. 11 as a linear combination of each axis error of an industrial machine;

FIG. 13 is a diagram showing a configuration of a data encoding device according to a second embodiment;

FIG. 14 is a diagram showing axis-dependent data divided into a plurality of grid regions;

FIG. 15 is a diagram showing an example of divided axis-dependent data;

FIG. 16 is a diagram showing the configuration of a data encoding device according to a third embodiment;

FIG. 17 is a flowchart showing a procedure of dividing axis-dependent data by a dynamic programming processor;

FIG. 18 is a diagram showing a divided section before expanding data of each axis (each axis error) by one row in the X positive direction;

FIG. 19 is a diagram showing a divided section after expanding data of each axis (each axis error) by one row in the X positive direction;

FIG. 20 is a diagram showing the configuration of a data encoding device according to a fourth embodiment;

FIG. 21 is a diagram showing approximation errors (vectors γ[X][Y]);

FIG. 22 is a diagram showing the configuration of a data encoding device according to a fifth embodiment;

FIG. 23 is a diagram showing approximation errors (vectors γ[X][Y]) including exception points larger than a predetermined tolerance;

FIG. 24 is a diagram showing exception points that are excluded and held due to being larger than a predetermined tolerance in the approximation errors (vectors γ[X][Y]);

FIG. 25 is a diagram showing the configuration of a data encoding device according to a sixth embodiment;

FIG. 26 is a diagram showing the configuration of a data encoding device according to a seventh embodiment; and

FIG. 27 is a flowchart showing a procedure of learning processing by a machine learning device 9.

### PREFERRED MODE FOR CARRYING OUT THE INVENTION

Hereinafter, embodiments of the present disclosure will be described in detail with reference to the drawings. In the description of the second and subsequent embodiments, the description of the configuration common to the first embodiment will be omitted as appropriate.

### First Embodiment

A data encoding device 1 according to the first embodiment is a data encoding device capable of encoding and compressing axis-dependent data depending on the coordinate values of each axis of an industrial machine such as an error amount or the like for use in error compensation of each axis of the industrial machine. As described above, since the axis-dependent data depending on the coordinate values of each axis of the industrial machine may have a white noise-like property in which the appearance frequency as a whole is uniform, it is difficult to compress the data by a conventional entropy encoding technique which uses the bias of the appearance frequency of the values on the data, that is, the smallness of the information entropy. On the contrary, the data encoding device 1 according to the present embodiment is capable of encoding and compressing axis-dependent data depending on the coordinate values of each axis of an industrial machine.

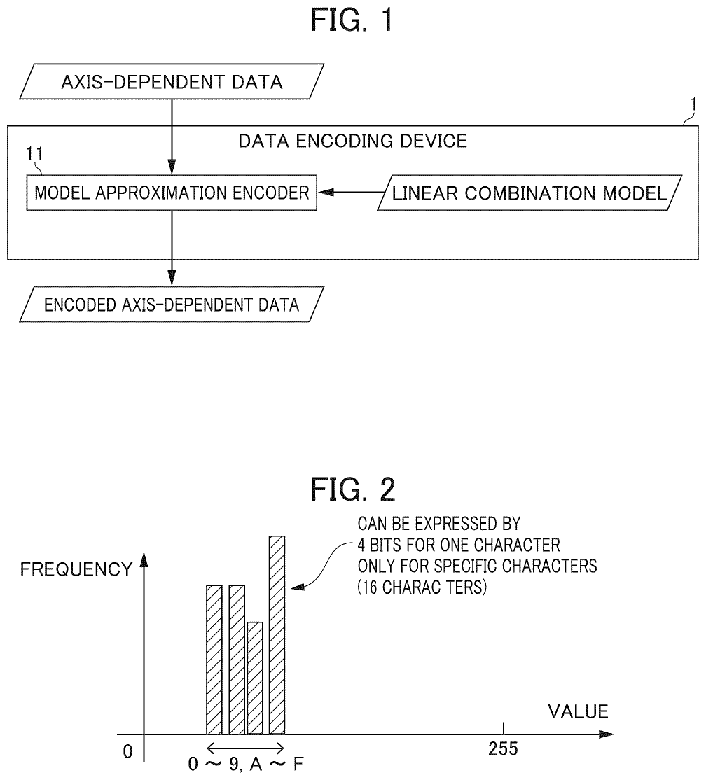

FIG. 1 is a diagram showing the configuration of the data encoding device 1 according to the first embodiment. As shown in FIG. 1, the data encoding device 1 includes a model approximation encoder 11. The model approximation encoder 11 generates encoded axis-dependent data obtained by encoding the axis-dependent data based on axis-dependent data and a linear combination model. In describing the configuration of the data encoding device 1, first, a conventional data encoding technique will be described.

As a data encoding technique, for example, an entropy encoding technique such as Huffman coding is conventionally known. The entropy encoding technique compresses data by utilizing bias in the appearance frequency of values on the data, i.e., the smallness of information entropy.

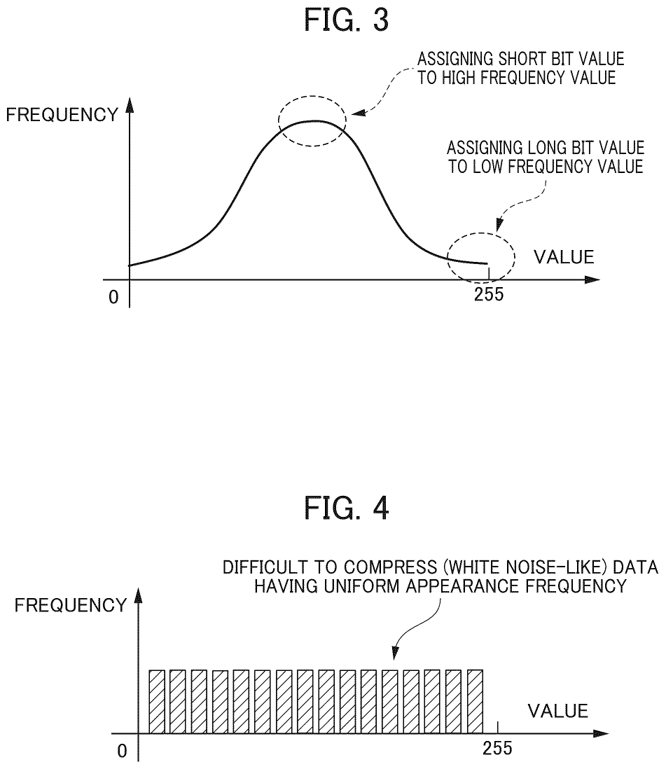

Herein, FIG. 2 is a diagram showing an example of a text file including only specific characters. Further, FIG. 3 is a diagram showing an example of data in which the appearance frequency of each value is represented by a specific distribution. In each of FIGS. 2 and 3, the horizontal axis indicates a bit value, and the vertical axis indicates an appearance frequency of each value. As shown in FIG. 2, for example, a text file including only 16 characters of 0 to 9 and A to F as specific characters normally requires 8 bits for expression of one character, but can be expressed by 4 bits at most for expression of one character by entropy encoding, so that data can be compressed to about half. Further, data having a non-uniform appearance frequency as shown in FIG. 3 can be compressed by assigning a short bit value to a high frequency value and assigning a long bit value to a low frequency value by entropy encoding.

On the other hand, FIG. 4 is a diagram showing data in which the appearance frequency of each value is uniform. Similarly to FIGS. 2 and 3, in FIG. 4, the horizontal axis indicates a bit value, and the vertical axis indicates the appearance frequency of each value. Since white noise-like data having a uniform appearance frequency as shown in FIG. 4 cannot utilize the above-described smallness of information entropy, it is difficult to compress the data by entropy encoding.

By the way, examples of the static error compensation of each axis of the industrial machine include pitch error compensation, straightness error compensation, and three-dimensional error compensation. The pitch error compensation is compensation of an error in a direction along the axial direction. The straightness error compensation is compensation of an error in a direction orthogonal to the axial direction. The three-dimensional error compensation is compensation of a three-dimensional spatial error. These error compensations are executed by inputting the amount of error (hereinafter, referred to as each axis error) measured for each coordinate value of each axis to the control device for the number of axes. As the number of input points increases, the accuracy of error compensation improves, but there is an upper limit to the size of data that can be inputted.

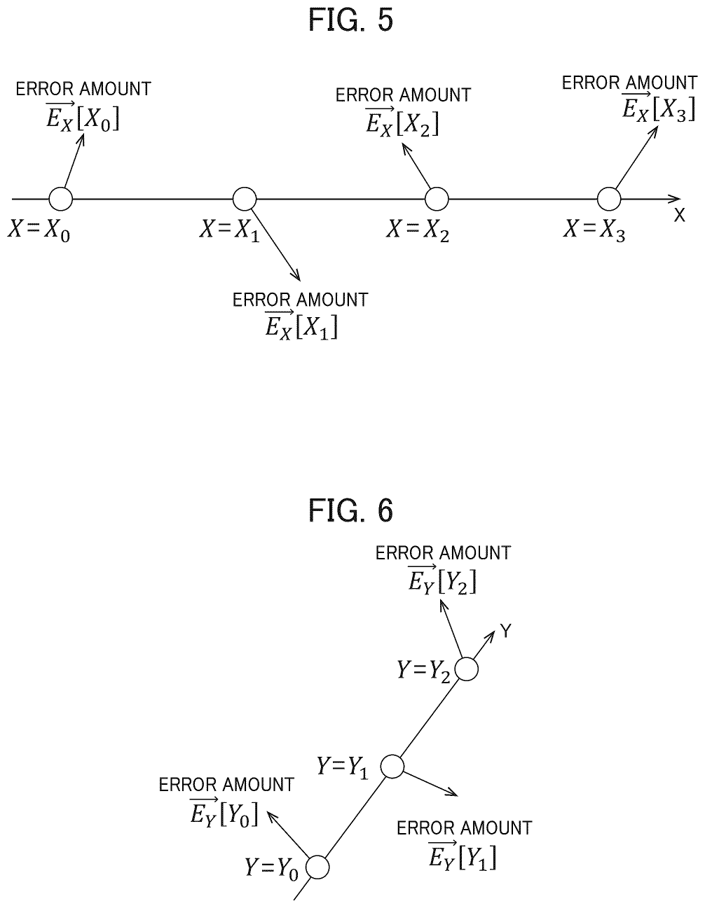

FIG. 5 is a diagram showing each axis error of the X-axis. Each axis error of the X axis is an error amount of each coordinate value measured when only the X axis is moved in a state where the Y axis and the Z axis are fixed. As shown in FIG. 5, the error amounts of the coordinate values X₀, X₁, X₂, and X₃ are displayed as vectors having different sizes and directions.

FIG. 6 is a diagram showing each axis error of the Y axis. Each axis error of the Y axis is an error amount of each coordinate value measured when only the Y axis is moved in a state where the X axis and the Z axis are fixed. As shown in FIG. 6, the error amounts of the coordinate values Y₀, Y₁, and Y₂ are displayed as vectors having different sizes and directions.

Here, in the error compensation of each axis, it is assumed that each axis error is linearly independent. That is, assuming that the error amount in each of the coordinate values X₁ . . . X_{L} (vector E[X¹] . . . [X^{L}]) is a linear combination of each axis error, the error amount is expressed by the following expression (1).

$$\begin{matrix}[ Expression 1 ] & \\ \vec{E} [ {X}^{1} ] … [ {X}^{L} ] := {\sum }_{l = 1}^{L} \vec{{E}_{{X}^{l}}} [ {X}^{l} ] & Expression ( 1 )\end{matrix}$$

In Expression (1) above, L represents the number of target axes subjected to error compensation. Further, X¹ represents the first compensation target axis.

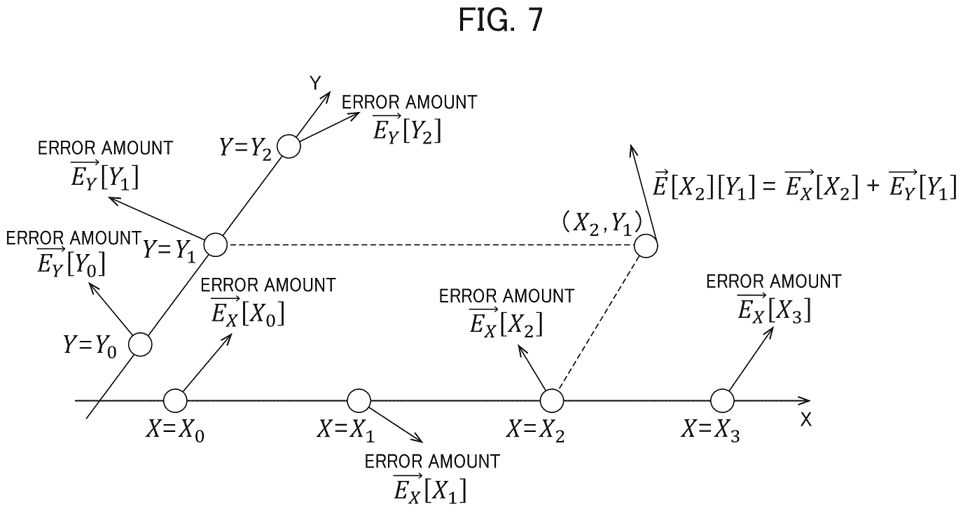

There are many situations where the above expression (1) based on the above assumption holds, and conventionally, error compensation for each axis is widely used. For example, FIG. 7 is a diagram showing an error amount in the coordinate value (X₂, Y₁). As shown in FIG. 7, the error amount (vector E[X₂][Y₁]) in the coordinate value (X₂, Y₁) can be regarded as a linear combination of the error amount (vector E_{X}[X₂]) in the coordinate value X₂ and the error amount (vector E_{Y}[Y₁]) in the coordinate value Y₁, and is represented by the following expression (2).

$$\begin{matrix}[ Expression 2 ] & \\ \vec{E} [ {X}_{2} ] [ {Y}_{1} ] = \vec{{E}_{X}} [ {X}_{2} ] + \vec{{E}_{Y}} [ {Y}_{1} ] & Expression ( 2 )\end{matrix}$$

However, when viewed as a whole, the appearance frequency of the value in each axis error (vector E_{X}[X], vector E_{Y}[Y]) or the appearance frequency of the value in the error amount (vector E[X][Y]) may be uniform in a white noise-like manner. In this case, it is difficult to compress the data by the conventional entropy encoding technique using the bias of the appearance frequency of the values on the data, that is, the smallness of information entropy.

In addition, each axis error may not be linearly independent, or the error amount (vector E[X¹] . . . [X^{L}]) may be determined by correlation between a plurality of axes. That is, the error amount (vector E[X¹] . . . [X^{L}]) includes the correlation term (vector δ[X¹] . . . [X^{L}]) as represented by the following expression (3), and may not be represented by a linear combination of each axis error.

$$\begin{matrix}[ Expression 3 ] & \\ \vec{E} [ {X}^{1} ] … [ {X}^{L} ] := {\sum }_{l = 1}^{L} \vec{{E}_{{X}^{l}}} [ {X}^{L} ] + \vec{δ} [ {X}^{1} ] … [ {X}^{L} ] & Expression ( 3 )\end{matrix}$$

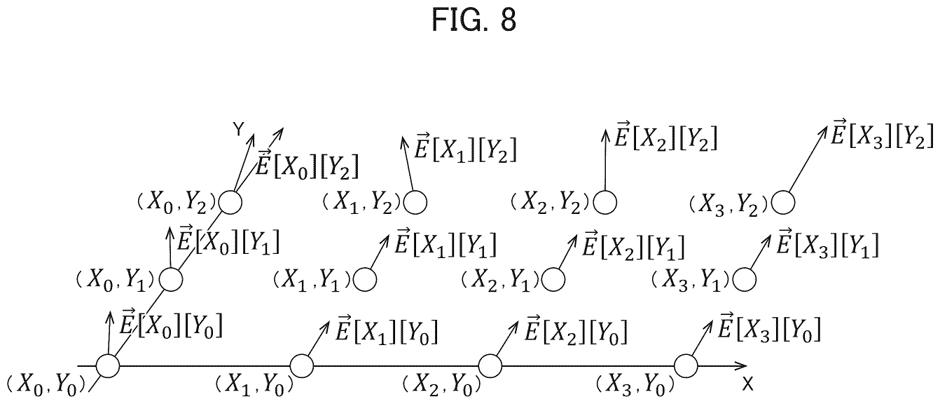

FIG. 8 is a diagram showing error amounts which cannot be expressed with a linear combination of each axis error. As shown in FIG. 8, when each axis error is not linear independent, the error amount (vector E[X¹] . . . [X^{L}]) needs to be an error amount including a correlation term (vector δ[X¹] . . . [X^{L}]) represented by the above-described expression (3), instead of the error amount represented by the above-described expression (1). In this case, since the error amount (hereinafter, referred to as a spatial error) is inputted to a control device and compensated for each space having a correlation with the error amount, it is called error compensation for each space.

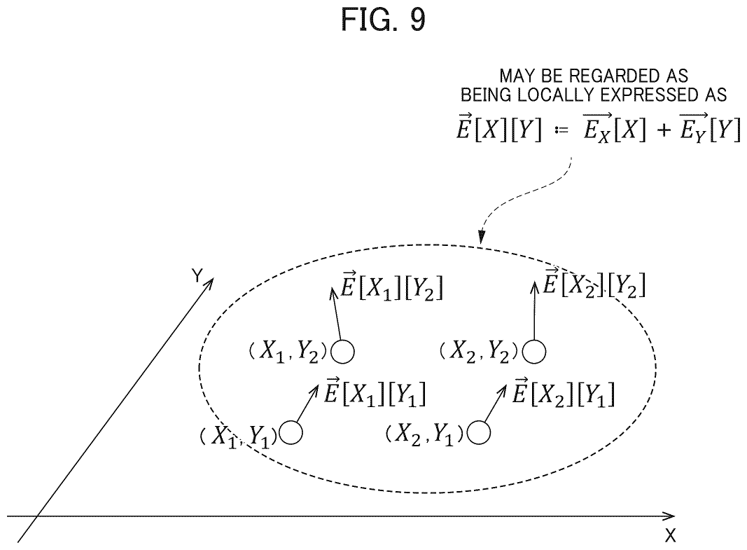

Here, the present inventor has found that the spatial error cannot be expressed as a linear combination of each axis error as a whole, but can be locally regarded as a linear combination of each axis error as in the case of each axis error. For example, FIG. 9 is a partial enlarged view of FIG. 8. Here, in the local region surrounded by the broken line in FIG. 9, the above correlation term (vector δ[X¹] . . . [X^{L}]) can be regarded as 0, and the spatial error can be represented as a linear combination of each axis error. That is, the spatial error (vector E[X][Y]) is represented by the sum of each axis error (vector E_{X}[X]) and each axis error (vector E_{Y}[Y]) as shown in the following expression (4). This indicates that the spatial error (vector E[X][Y]) can be approximated as a linear combination of an error amount (vector E_{X}[X]) in one row in the X-axis direction and an error amount (vector E_{Y}[Y]) in one row in the Y-axis direction, among data of each axis (each axis error) on a plurality of coordinate points in a grid manner. It should be noted that the examples of the local region include a central region of a movable range of the industrial machine.

$$\begin{matrix}[ Expression 4 ] & \\ \vec{E} [ X ] [ Y ] := \vec{{E}_{X}} [ X ] + \vec{{E}_{Y}} [ Y ] & Expression ( 4 )\end{matrix}$$

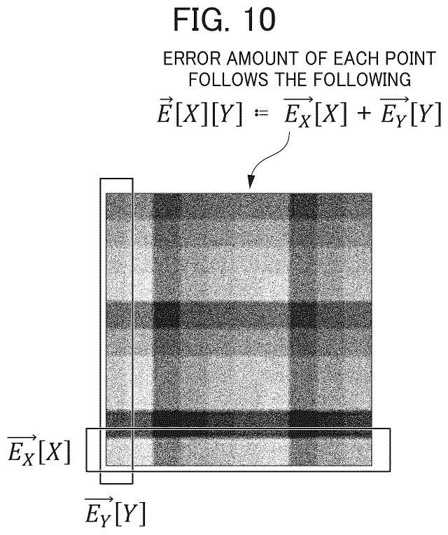

However, when viewed as a whole, the appearance frequency of values in the spatial error (vector E[X][Y]) may be uniform in a white noise-like manner, and thus it is difficult to compress the data by a conventional entropy encoding technique using the smallness of information entropy. For example, FIG. 10 is a diagram showing a bitmap image visualizing an error map in a case where the target axes of error compensation are two axes of the X axis and the Y axis, and RGB values of each pixel correspond to the error amount vector E. Further, the error amount (vector E[X][Y]) of each pixel is represented by the sum of the vector E_{X}[X] and the vector E_{Y}[Y] in accordance with Expression (4). For example, in a case where the number of pixels of the bitmap image shown in FIG. 10 is 10×10 and 374 bytes, when the bitmap image is encoded by ZIP compression, which is a typical entropy encoding technique, 393 bytes are obtained. As described above, it can be seen that the conventionally known entropy encoding has no compression effect, and in some cases, the data size increases, resulting in an inverse effect.

In view of the above, in the present embodiment, even for axis-dependent data depending on coordinate values of each axis of an industrial machine such as an error amount or the like for use in error compensation of each axis of the industrial machine, the property is utilized which can be locally regarded as a linear combination of each axis error as represented by the above-described expression (1). As a result, it is possible for the data encoding device 1 according to the present embodiment to encode and compress the axis-dependent data, which has been difficult in the related art.

Referring back to FIG. 1, the data encoding device 1 according to the present embodiment includes a computer including, for example, memory such as ROM (read only memory) and RAM (random access memory), a CPU (control processing unit), an operation unit such as a keyboard, a display, and a communication controller, which are connected to each other via a bus. The functions and operations of the functional units described later are achieved by cooperation of a CPU, memory, and control programs stored in the memory, which are mounted on the computer.

The data encoding device 1 according to the present embodiment may be provided in, for example, a numerical control device (CNC: Computerized Numerical Control) or a robot control device corresponding to a control device of a machine tool or an industrial machine such as a robot. Alternatively, the data encoding device 1 may be provided in an external computer or the like so as to be able to communicate with these control devices.

The model approximation encoder 11 according to the present embodiment included in the data encoding device 1 generates encoded axis-dependent data obtained by encoding the axis-dependent data based on a portion of the axis-dependent data depending on coordinate values of each axis of the industrial machine and a linear combination model that approximates the axis-dependent data as a linear combination of data of each axis (each axis error) of the industrial machine. The axis-dependent data is inputted from, for example, the above-described control device or the like. Further, the linear combination model is stored in, for example, the storage of the data encoding device 1.

Here, each axis of the industrial machine indicates, for example, each axis of the machine tool, that is, the X axis, the Y axis, and the Z axis. Further, examples of the axis-dependent data include the error amount for use in the error compensation of each axis of the industrial machine and, for example, an installation error amount of a relatively large workpiece whose displacement is different for each coordinate value due to the influence of deflection due to its own weight. Each of the error amount and the installation error amount of the workpiece is data depending on coordinate values of each axis of the industrial machine.

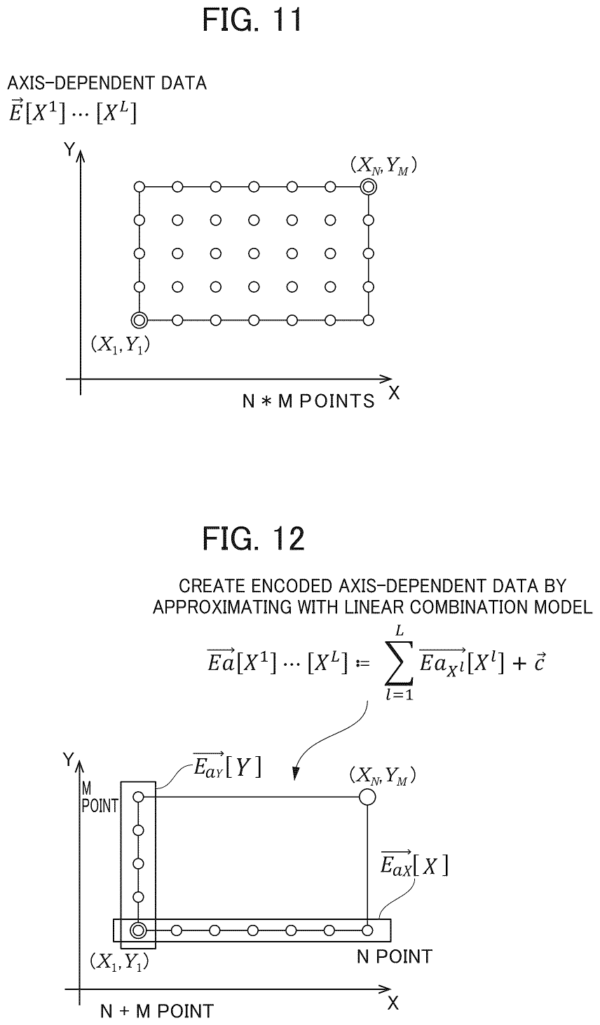

Hereinafter, the model approximation encoding using a linear combination model by the model approximation encoder 11 according to the present embodiment will be described in detail with reference to FIGS. 11 and 12.

FIG. 11 is a diagram showing an example of axis-dependent data. In the example shown in FIG. 11, axis-dependent data in a case where two axes, i.e., the X-axis and the Y-axis, are used as target axes for error compensation and the like is shown. The axis-dependent data shown in FIG. 11 is axis-dependent data of a specific local region in axis-dependent data in which there is no bias in the appearance frequency of values on the data as a whole in terms of, for example, error amounts of each axis of the industrial machine, and is axis-dependent data that can be approximated by a linear combination model described later. The example of the axis-dependent data shown in FIG. 11 includes data of each axis (each axis error) of N×M points in total.

FIG. 12 is a diagram showing a linear combination model approximating the axis-dependent data of FIG. 11 as a linear combination of each axis error of an industrial machine. As described above, even when the error amount (vector E[X¹] . . . [X^{L}]) conforms to the model represented by Expression (3) and the influence of the correlation term (vector δ[X¹] . . . [X^{L}]) is considered to be strong as a whole, it is considered that a region that can be approximated by the linear combination model represented by the mathematical Expression (1) locally exists. For such a region that can be approximated, as shown in FIG. 12, the error amount can be expressed by an approximation model (vector Ea[X¹] . . . [X^{L}]) as a linear combination model represented by the following Expression (5). That is, the error amount can be approximated as a linear combination of an error amount (vector Ea_{X}[X]) in one row in the X-axis direction and an error amount (vector Ea_{Y}[Y]) in one row in the Y-axis direction. In the example shown in FIG. 12, data of each axis (each axis error) after approximation becomes N+M points in total, and it can be seen that the axis-dependent data can be compressed.

$$\begin{matrix}[ Expression 5 ] & \\ \vec{Ea} [ {X}^{1} ] … [ {X}^{L} ] := {\sum }_{l = 1}^{L} \vec{{Ea}_{{X}^{l}}} [ {X}^{l} ] + \vec{c} & Expression ( 5 )\end{matrix}$$

In Expression (5), X¹ and X^{L} are represented by Expression (6) below, and a vector c is defined as an average value as represented by Expression (7) below. The vector Eaₓ¹[X¹] is expressed by the following expression (8). Further, L represents the number of target axes subjected to error compensation, X¹ represents the first compensation target axis, and N¹ represents the error amount point of the first compensation target axis.

$$\begin{matrix}[ Expression 6 ] & \\ {X}^{1} := [ {X}_{1}^{1} , … , {X}_{{N}^{1}}^{1} ] … {X}^{L} := [ {X}_{1}^{L} , … , {X}_{{N}^{L}}^{L} ] & Expression ( 6 )\end{matrix}$$

$$\begin{matrix}[ Expression 7 ] & \\ \vec{c} := \frac{1}{{\sum }_{l = 1}^{L} {N}^{l}} {\sum }_{{X}^{1} = 1}^{{N}^{1}} … {\sum }_{{X}^{L} = 1}^{{N}^{L}} ( \vec{E} [ {X}^{1} ] … [ {X}^{L} ] - {\sum }_{l = 1}^{L} \vec{{Ea}_{{X}^{l}}} [ {X}^{l} ] ) & Expression ( 7 )\end{matrix}$$

$$\begin{matrix}[ Expression 8 ] & \\ \vec{{Ea}_{{X}^{l}}} [ {X}^{l} ] := \vec{E} [ {x}^{1} ] … [ {X}^{l} ] … [ {x}^{l} ] & Expression ( 8 )\end{matrix}$$

provided that X is any value that satisfies

$$( {X}_{1}^{p} \leq {x}^{p} \leq {X}_{{N}^{p}}^{p} )$$

and common in each {right arrow over (Eaₓ_{^{l}})}[X^{l}]

In Expression (8), while X represents a one-dimensional axial space, x represents an element belonging to the space. The symbol p is any value from 1 to L. For example, x³ indicates a certain value that can be taken by the axis X³.

When the vector c is defined as in the above Expression (7), the approximation model (vector Ea[X₁] . . . [X_{L}]) as the linear combination model becomes a maximum likelihood estimation model that minimizes the evaluation function J expressed by the following Expression (9). That is, the evaluation function J is expressed as the sum of squares of the difference between the original error amount before approximation (vector E[X¹] . . . [X^{L}]) and the error amount after approximation (vector Ea[X¹] . . . [X^{L}]), as represented by the following Expression (9), and the approximation model (vector Ea[X₁] . . . [X_{L}]) as the linear combination model is determined so that the evaluation function J is minimized. The approximation model as the linear combination model thus determined is stored in, for example, the storage of the data encoding device 1, and is used for model approximation encoding by the model approximation encoder 11.

$$\begin{matrix}[ Expression 9 ] & \\ J := {\sum }_{{X}^{1} = 1}^{{N}^{1}} … {\sum }_{{X}^{L} = 1}^{{N}^{L}} ( \vec{E} [ {X}^{1} ] … [ {X}^{L} ] - \vec{Ea} [ {X}^{1} ] … [ {X}^{L} ] ) \cdot ( \vec{E} [ {X}^{1} ] … [ {X}^{L} ] - \vec{Ea} [ {X}^{1} ] … [ {X}^{L} ] ) & Expression ( 9 )\end{matrix}$$

According to the present embodiment, the following advantageous effects are achieved.

The data encoding device 1 according to the present embodiment includes the model approximation encoder 11 that generates the encoded axis-dependent data obtained by encoding the axis-dependent data based on a portion of the axis-dependent data depending on the coordinate values of each axis of the industrial machine, and the linear combination model that approximates the axis-dependent data as the linear combination of data of each axis (each axis error) of the industrial machine. Conventionally, it has been difficult to compress axis-dependent data having a uniform appearance frequency as a whole such as each axis error amount or the like of an industrial machine by a conventional entropy encoding technique using a bias in the appearance frequency of values on the data, that is, the smallness of information entropy. On the contrary, according to the present embodiment, it is possible to encode and compress the axis-dependent data, which has been conventionally difficult to compress, by approximating a portion of the axis-dependent data as a linear combination of each axis data (each axis error). In addition, by using the encoded axis-dependent data encoded and compressed according to the present embodiment, it is possible to increase data such as the error amount that is inputtable to the control device or the like of the industrial machine, without increasing the storage capacity, and it is possible to more accurately compensate for the error of the industrial machine.

### Second Embodiment

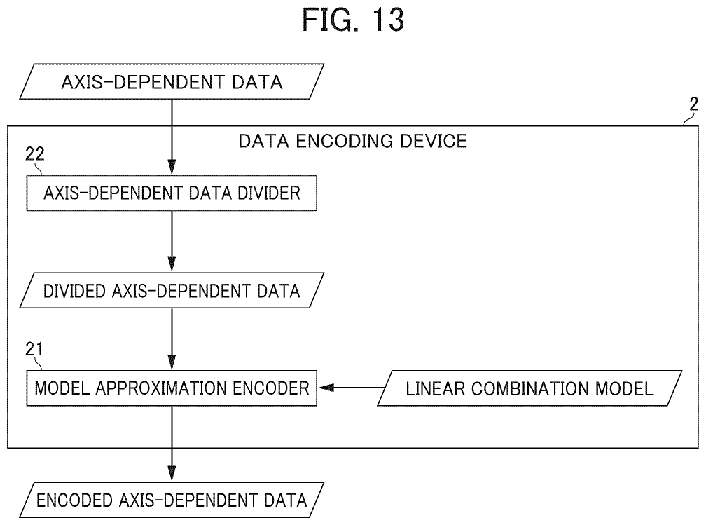

FIG. 13 is a diagram showing a configuration of a data encoding device 2 according to the second embodiment. As shown in FIG. 13, the data encoding device 2 according to the second embodiment differs from the data encoding device 1 according to the first embodiment in that the data encoding device 2 includes an axis-dependent data divider 22. In addition, a model approximation encoder 21 according to the second embodiment differs from the model approximation encoder 11 of the first embodiment in that the model approximation encoder 21 performs the model approximation encoding based on divided axis-dependent data generated by dividing the axis-dependent data into a plurality of pieces of data and the linear combination model described above. The configuration other than these differences is the same as that of the first example.

The above-described data encoding device 1 according to the first embodiment performs model approximation encoding of a linear combination model on the assumption that a portion of axis-dependent data having a uniform appearance frequency in a white noise-like manner as a whole can be regarded as a linear combination of data of each axis (each axis error). On the other hand, the data encoding device 2 according to the present embodiment actively divides the axis-dependent data into a plurality of regions to generate a plurality of regions that can be regarded as the linear combination of data of each axis (each axis error), thereby enabling the execution of the model approximation encoding of the linear combination model more reliably.

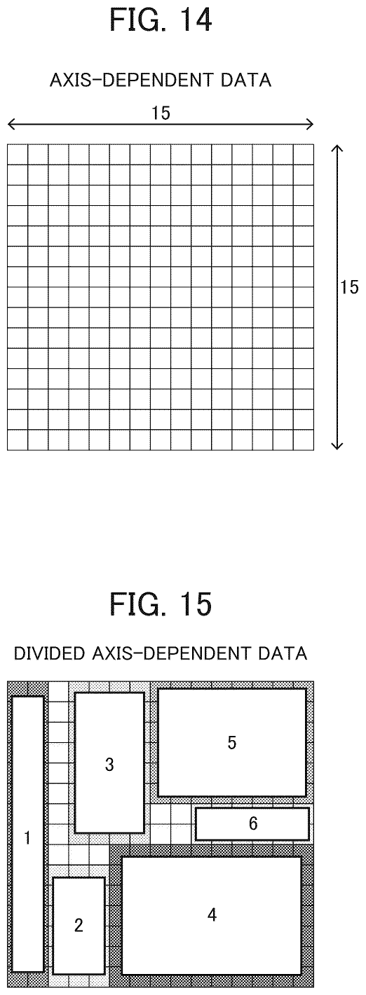

The axis-dependent data divider 22 divides the axis-dependent data to generate a plurality of divided axis-dependent data. Here, FIG. 14 is a diagram showing axis-dependent data divided into a plurality of grid regions. As shown in FIG. 14, the axis-dependent data inputted to the data encoding device 2 is divided into a plurality of grid regions according to data of each axis (each axis error) on each coordinate value, for example. In the example shown in FIG. 14, the axis-dependent data is divided into a grid of 15×15=225 points. The axis-dependent data divider 22 divides the axis-dependent data into a plurality of sections based on the grid, for example.

The method of dividing the axis-dependent data by the axis-dependent data divider 22 is not particularly limited, but it is preferable to divide the axis-dependent data so as to generate a plurality of regions that can be regarded as the linear combination of data of each axis (each axis error). In particular, it is preferable that the axis-dependent data divider 22 divides the axis-dependent data into a plurality of regions that can be best approximated (compressed).

FIG. 15 is a diagram showing an example of divided axis-dependent data. In the example shown in FIG. 15, the axis-dependent data inputted to the data encoding device 2 is divided into five sections 1 to 5 by the axis-dependent data divider 22. That is, the respective data in the respective regions of the five divided sections 1 to 5 correspond to the divided axis-dependent data, and each of the divided axis-dependent data can be regarded as a linear combination of data of each axis (each axis error), and the model approximation encoding of the linear combination model by the model approximation encoder 21 described later is possible. On the other hand, outside these five divided sections 1 to 5, the axis-dependent data cannot be regarded as a linear combination of data of each axis (each axis error), and model approximation encoding of the linear combination model is impossible.

The model approximation encoder 21 generates encoded axis-dependent data based on the plurality of divided axis-dependent data and the linear combination model. As described above, in each region of the plurality of divided sections 1 to 5, the axis-dependent data can be regarded as a linear combination of data of each axis (each axis error). Therefore, the model approximation encoder 21 performs model approximation encoding of the linear combination model on each of the divided axis-dependent data to generate the encoded axis-dependent data that are model-approximated and compressed.

According to the present embodiment, the following advantageous effects are achieved.

The data encoding device 2 according to the present embodiment includes the axis-dependent data divider 22 that divides axis-dependent data and generates a plurality of divided axis-dependent data. In addition, the model approximation encoder 21 is configured to generate the encoded axis-dependent data based on the plurality of divided axis-dependent data and the linear combination model. With such a configuration, according to the present embodiment, by actively dividing the axis-dependent data into a plurality of regions, it is possible to generate each of the plurality of regions that can be regarded as a linear combination of data of each axis (each axis error), and by performing the model approximation encoding of the linear combination model for each region, it is possible to more reliably compress the axis-dependent data, which has been difficult to compress conventionally.

### Third Embodiment

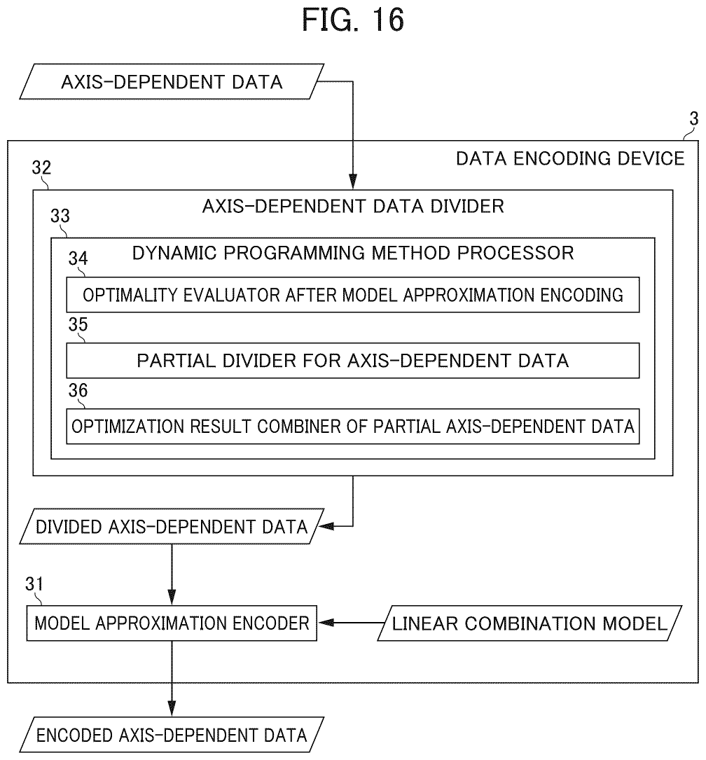

FIG. 16 is a diagram showing a configuration of a data encoding device 3 according to a third embodiment. As shown in FIG. 16, a data encoding device 3 according to the third embodiment differs from the second embodiment in that the configuration of an axis-dependent data divider 32 differs from that of the axis-dependent data divider 22 described above. The configurations other than this difference are the same as those of the second example.

In the above-described data encoding device 2 according to the second embodiment, the method of dividing the axis-dependent data is not particularly limited, but in the data encoding device 3 according to the third embodiment, the axis-dependent data is divided using a dynamic programming method. That is, by using the dynamic programming method, the optimal division of the axis-dependent data can be executed, and the axis-dependent data can be best approximated and compressed.

As shown in FIG. 16, the axis-dependent data divider 32 includes a dynamic programming processor 33. The dynamic programming processor 33 generates optimal divided axis-dependent data by executing the dynamic programming method. Specifically, the dynamic programming processor 33 includes, as functional units for executing the dynamic programming method, an optimality evaluator 34 after model approximation encoding, a partial divider 35 of the axis-dependent data, and an optimization result combiner 36 of the partial axis-dependent data.

Here, the dynamic programming method executed by the dynamic programming processor 33 will be described in detail.

The dynamic programming method is a generic algorithm for solving optimized problems. The dynamic programming method is an algorithm having the following two features. The first feature is to solve recursively. That is, the first feature is characterized in that a problem is divided into partial problems of a small scale, the partial problems are recursively optimized, and the optimization results of the partial problems are combined to obtain a solution of the original problem of a larger scale. The second feature is that the processing load can be reduced by recording the optimization results. That is, the second feature is characterized in that, although the same problems may appear many times in the process of recursively solving the problems, in order to omit the calculation of the problem which has been solved, the optimization result of a problem which has been solved once is recorded and reused.

Therefore, the dynamic programming processor 33 of the present embodiment includes an optimality evaluator 34 after model approximation encoding as a means for evaluating the optimality of the result. That is, the optimality evaluator 34 after the model approximation encoding evaluates the optimality of the encoded axis-dependent data. The evaluation of the optimality of the encoded axis-dependent data can be performed based on, for example, whether an approximation error amount after the model approximation encoding is within a predetermined constraint tolerance. In addition, as described in detail in a fourth embodiment to be described later, the approximation error amount after the model approximation encoding is a difference between the original error amount before the model approximation encoding described in the above-described first embodiment and the error amount after the model approximation encoding. The constraint tolerance may be, for example, an allowable approximation error value or an allowable number of points of data exceeding the allowable approximation error value.

In addition, the dynamic programming processor 33 according to the present embodiment includes the partial divider 35 of axis-dependent data as a means for dividing a problem into partial problems. The partial divider 35 of the axis-dependent data divides the axis-dependent data into a plurality of portions to generate partial axis-dependent data. For example, the partial divider 35 of the axis-dependent data divides the axis-dependent data into predetermined designated sections in accordance with a predetermined division criterion stored in advance, and reduces the resultant data by one point in each of the positive direction and the negative direction of each axis such as the X axis and the Y axis to optimize the resultant data, thereby obtaining a plurality of portions of the axis-dependent data. The division of the axis-dependent data by the partial divider 35 of the axis-dependent data will be described later in detail.

In addition, the dynamic programming processor 33 according to the present embodiment includes the optimization result combiner 36 for the partial axis-dependent data as a means for combining the optimization results of the partial problems. The optimization result combiner 36 for the partial axis-dependent data expands and combines the partial axis-dependent data to generate optimal divided axis-dependent data. The optimization result combiner 36 for the partial axis-dependent data optimizes the partial axis-dependent data generated by dividing the axis-dependent data by the partial divider 35 of the above-described axis-dependent data by expanding the partial axis-dependent data by one point in each of the positive direction and the negative direction of each axis such as the X axis and the Y axis. The generation of the optimal divided axis-dependent data by the optimization result combiner 36 for the partial axis-dependent data will be described later in detail.

Hereinafter, the division of the axis-dependent data by the dynamic programming processor 33 will be described in detail with reference to FIGS. 14, 15, 17, and 18.

As shown in FIG. 14, the axis-dependent data is divided into, for example, a grid of 15×15=225 points. When such axis-dependent data are divided into sections by the dynamic programming processor 33, for example, divided axis-dependent data as shown in FIG. 15 are obtained. In the division into sections of the axis-dependent data by the dynamic programming processor 33, an approximation error of each error amount in a case where each region of the divided sections is approximated by the above-described approximation model is set to fall within a constraint allowable amount. Further, each of the points at which the approximation error does not fall within the constraint allowable amount is allowed up to the constraint allowable number. Nevertheless, the points that cannot be approximated or do not meet the constraint are minimized in number. As a result, for example, the number of data points 225 can be compressed to 92 points, and the data size can be reduced.

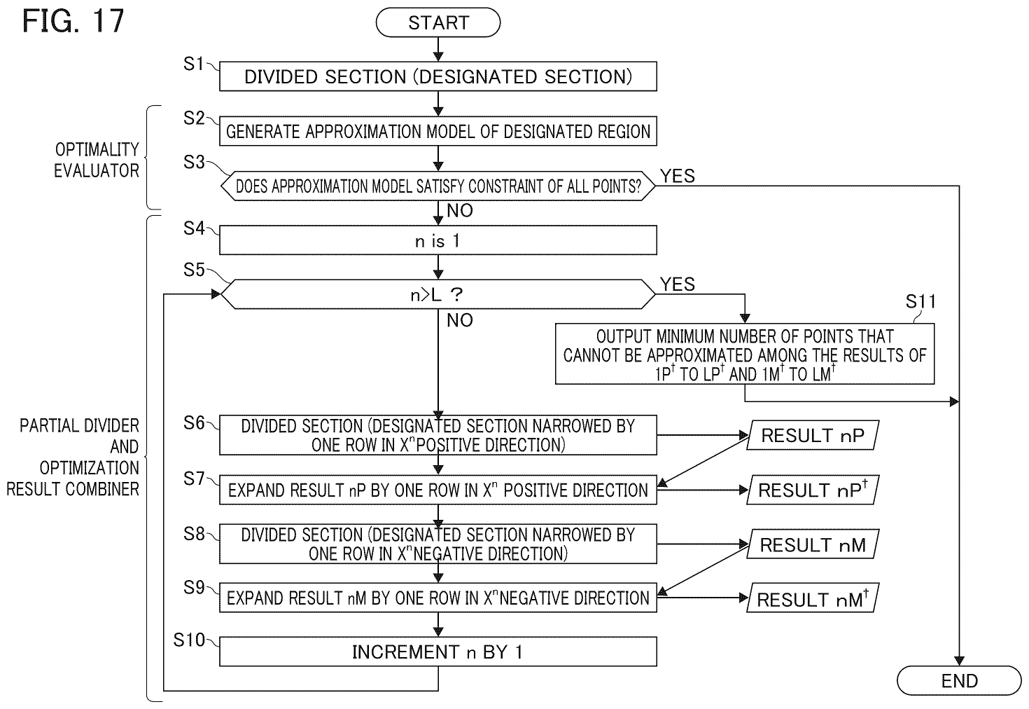

FIG. 17 is a flowchart showing a procedure of dividing the axis-dependent data by the dynamic programming processor 33. The division of the axis-dependent data by the dynamic programming processor 33 is executed by recursively searching for optimal divided sections of the axis-dependent data by the dynamic programming method.

In Step S1, the axis-dependent data is divided into predetermined designated sections. However, in a case of a region in which the division processing of the axis-dependent data has been performed by the dynamic programming processor 33, the held processing result may be reflected in this step. Thereafter, the processing proceeds to Step S2.

In Step S2, an approximation model of each of the regions of the designated sections (designated regions) divided in Step S1 is generated. Specifically, an approximation model (vectors Ea[X₁] . . . [X_{L}]) as a linear combination model described in the first embodiment is generated for each designated region. Thereafter, the processing proceeds to Step S3.

In Step S3, it is determined whether the approximation models of the designated regions generated in Step S2 satisfy the constraint of all points. Examples of the constraint include whether the approximation errors of all points are within the allowable value, and whether the number of points at which the approximation errors are not within the allowable value is within the allowable number of points. When it is determined as YES, it is determined that the axis-dependent data has been optimally divided and optimally divided axis-dependent data has been obtained, and the processing ends. On the other hand, when it is determined as NO, the processing proceeds to Step S4.

In Step S4, n is set to the initial value 1. Here, the value of n represents each axis and, for example, in a case where the axis configuration is a total of the two axes of the X axis and the Y axis, the value of n represents the X axis when n is 1, and the value of n represents the Y axis when n is 2. Thereafter, the processing proceeds to Step S5.

In Step S5, it is determined whether n is larger than L. Here, L is the number of axes in the designated section of the axis-dependent data. For example, in a case of the two axes of the X axis and the Y axis, L is 2. When it is determined as YES, the processing proceeds to Step S11. On the other hand, when it is determined as NO, the processing proceeds to Step S6.

The processing of steps S6 to S10 is a case where n is equal to or less than L, and when the number of axes is the two axes of the X axis and the Y axis, and when n is 1, it indicates processing for the X axis, and when n is 2, it indicates processing for the Y axis.

In Step S6, the axis-dependent data is divided into designated sections in which data of each axis (each axis error) is narrowed by one row in the Xⁿ positive direction from the designated sections of Step S1. That is, a new divided section is executed in which data of each axis (each axis error) is reduced by one row in the Xⁿ positive direction. The Xⁿ positive direction indicates the X-axis positive direction when n is 1. The result is outputted as an optimization result nP. When n is 1, the optimization result 1P is outputted. Thereafter, the processing proceeds to Step S7.

In Step S7, the optimization result nP obtained in Step S6 is expanded in the Xⁿ positive direction by one row of data of each axis (each axis error). The result is outputted as an optimization result nP⁺. When n is 1, the optimization result 1P⁺ is outputted. Since n can be in the range of 1 to L, the optimization results 1P to LP⁺ can be obtained by this step. Thereafter, the processing proceeds to Step S8.

In Step S8, the axis-dependent data is divided into designated sections in which the data of each axis (each axis error) is narrowed by one row in the Xⁿ negative direction from the designated sections in Step S1. That is, a new divided section is executed which is reduced by one row of data of each axis (each axis error) in the negative Xⁿ direction. The Xⁿ negative direction indicates the X-axis negative direction when n is 1. The result is outputted as an optimization result nM. When n is 1, the optimization result 1M is outputted. Thereafter, the processing proceeds to Step S9.

In Step S9, the optimization result nM obtained in Step S8 is expanded in the Xⁿ negative direction by one row of data of each axis (each axis error). The result is outputted as an optimization result nM⁺. When n is 1, the optimization result 1M⁺ is outputted. Since n can be in the range of 1 to L, this step results in optimization results 1M to LM⁺. Thereafter, the processing proceeds to Step S10.

In Step S10, n is incremented by 1. Thereafter, the processing returns to Step S5.

In addition, Step S11 is processing when n is larger than L, and when the number of axes is two axes, i.e., the X axis and the Y axis, Step S11 is performed after the processing for the X axis and the Y axis is completed in Steps S6 to S10. In Step S11, among the optimization results 1P to LP⁺ and 1M to LM⁺ obtained in Steps S6 to S10, those having the smallest number of points that cannot be approximated are outputted. That is, for each of the optimization results 1P to LP⁺ and 1M to LM⁺, the number of points that cannot be approximated for which the approximation model generated in Step S3 does not satisfy the above-described constraint is calculated, and those having the minimum number of points that cannot be approximated, approximated best, and compressed most are obtained, and then the processing is ended.

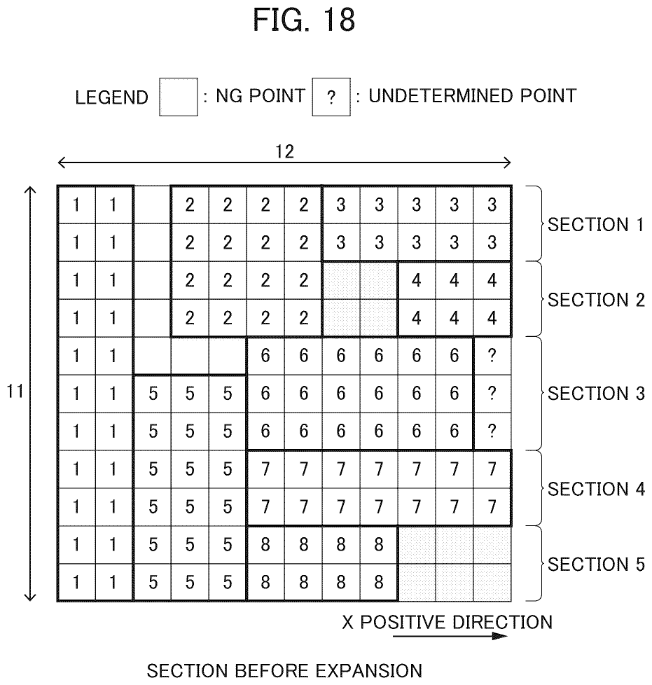

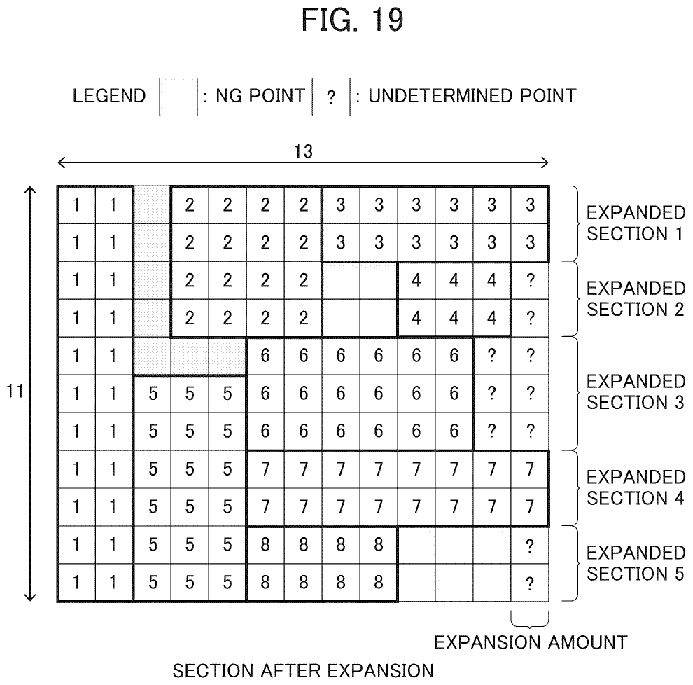

Here, the procedure of expanding one row of data of each axis (each axis error) in the X positive direction in the above-described Step S7 will be described in more detail with reference to specific examples shown in FIGS. 18 and 19. FIG. 18 is a diagram showing divided sections before expanding data of each axis (each axis error) by one row in the X positive direction. In addition, FIG. 19 is a diagram showing divided sections after expanding the data of each axis (each axis error) by one row in the X positive direction. In FIGS. 18 and 19, different numbers are assigned to the respective divided sections.

As shown in FIG. 18, first, sections 1 to 5 are extracted as continuous sections that appear at the end portion in the X positive direction of the sections before expansion by one row of data of each axis (each axis error).

Then, each of the extracted sections 1 to 5 is expanded by one row of data of each axis (each axis error) to generate expanded sections 1 to 5, as shown in FIG. 19.

Next, for each of the expanded sections 1 to 5, it is checked whether the above-described approximation model satisfies the above-described constraint. If the constraint is satisfied, the expanded sections are set as the new sections. In the example shown in FIG. 19, since the expanded sections 1 and 4 satisfy the constraint, they are set as new sections.

If the constraint is not satisfied, the sections of expansion amount are set as undetermined sections. In the example shown in FIG. 19, since the expanded section 2 does not satisfy the constraint, it is set as an undetermined section.

When each of the undetermined sections is equal to or larger than a predetermined area (for example, 2×2), it is checked whether the above-described approximation model satisfies the above-described constraint. In the example shown in FIG. 19, since the expanded section 3 is equal to or larger than a predetermined area (for example, 2×2), this determination is performed. Until then, this expanded section is also determined as an undetermined section.

In addition, in a case where the section before expansion is an NG section, that is, a section that does not satisfy the constraint and cannot be approximated, the section of the expansion amount is an undetermined section. In the example shown in FIG. 19, since the expanded section 5 corresponds to the NG section, it is set as an undetermined section.

As described above, there is a case where an undetermined section remains until the end. Such a section may finally be an NG section, that is, a section that does not satisfy the constraint and cannot be approximated.

According to the present embodiment, the following advantageous effects are achieved.

The data encoding device 3 according to the present embodiment includes the dynamic programming processor 33 that generates optimal divided axis-dependent data by executing the dynamic programming. In addition, the dynamic programming processor 33 includes the optimality evaluator 34 that evaluates the optimality of the encoded axis-dependent data, the partial divider 35 that divides the axis-dependent data into a plurality of portions to generate partial axis-dependent data, and the optimization result combiner 36 that combines the optimization results of the partial axis-dependent data to generate optimal divided axis-dependent data. With such a configuration, according to the present embodiment, since the axis-dependent data can be divided into the optimal divided axis-dependent data that can be compressed while minimizing the number of pieces of data, it is possible to generate an optimal plurality of regions that can each be regarded as a linear combination of data of each axis (each axis error), and by executing the model approximation encoding of the linear combination model for each region, it is possible to further compress the axis-dependent data, which has been difficult to compress conventionally.

### Fourth Embodiment

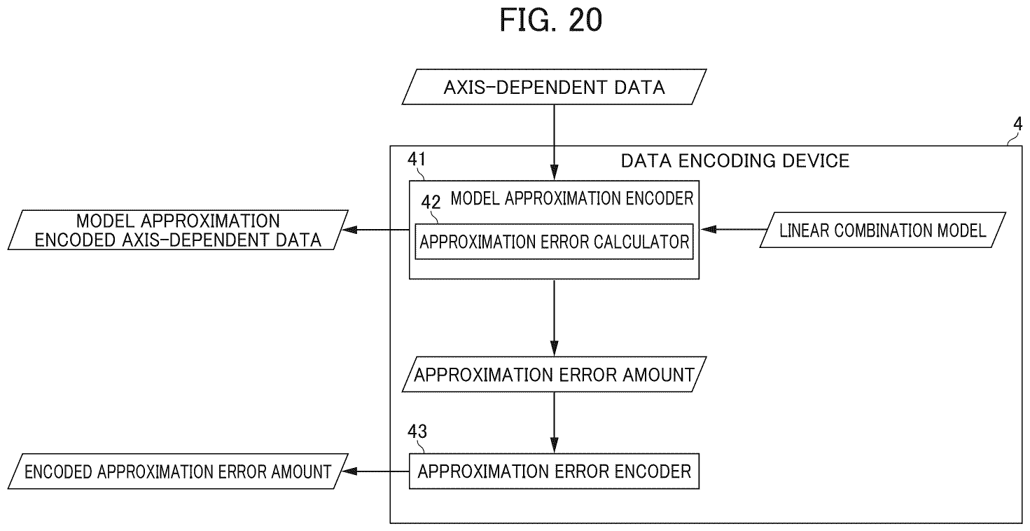

FIG. 20 is a diagram showing a configuration of a data encoding device 4 according to a fourth embodiment. As shown in FIG. 20, the data encoding device 4 according to the fourth embodiment differs from the model approximation encoder 11 according to the first embodiment in that a model approximation encoder 41 includes an approximation error calculator 42. The data encoding device 4 according to the fourth embodiment differs from the data encoding device 1 according to the first embodiment in that the data encoding device 4 includes an approximation error encoder 43. The configuration other than these differences are the same as those of the first example.

The approximation error calculator 42 calculates an approximation error amount. The approximation error calculator 42 according to the present embodiment is provided in the model approximation encoder 41, and calculates an approximation error amount in accordance with model approximation encoding of the axis-dependent data. This approximation error amount will be described later in detail.

The approximation error encoder 43 encodes the approximation error amount to generate an encoded approximation error amount. Since the approximation error amount calculated by the approximation error calculator 42 has a bias in the appearance frequency of values on data as described later and the information entropy is small in many cases, it is possible to encode the approximation error amount and compress the data by conventionally known entropy encoding. Alternatively, the data compression may be performed by performing the model approximation encoding of the linear combination model executed by the model approximation encoder 41.

Hereinafter, the approximation error amount and the encoding of the approximation error amount by the approximation error encoder 43 will be described in more detail.

As described in the above-mentioned first embodiment, when the error amount is expressed by the approximation model (vector Ea[X¹] . . . [X^{L}]) as the linear combination model expressed by the above-described Expression (5), the approximation errors (vectors γ[X1] . . . [XL]) are expressed by the following Expression (10).

$$\begin{matrix}[ Expression 10 ] & \\ \vec{γ} [ {X}^{1} ] … [ {X}^{L} ] := \vec{E} [ {X}^{1} ] … [ {X}^{L} ] - \vec{Ea} [ {X}^{1} ] … [ {X}^{L} ] & Expression ( 10 )\end{matrix}$$

In Expression (10), vectors E[X¹] . . . [X^{L}] are original error amounts before model approximation, and vectors Ea[X¹] . . . [X^{L}] are error amounts after model approximation. It can be seen from Expression (10) that these differences are approximation errors (vectors γ[X¹] . . . [X^{L}]).

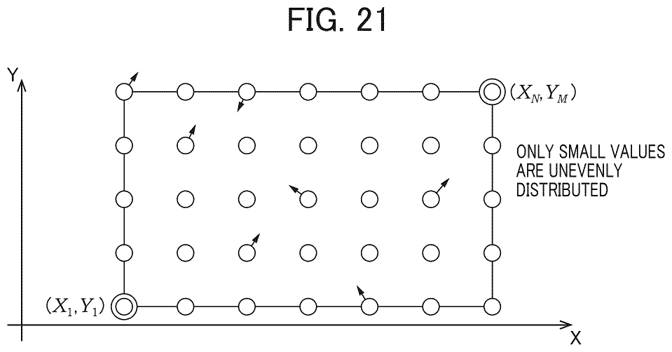

Here, since the approximation model (vector Ea[X¹] . . . [X^{L}]) is the maximum likelihood estimation model, the approximation errors (vectors γ[X¹] . . . [X^{L}]) are minimized and become only very small values. Here, FIG. 21 is a diagram showing approximation errors (vectors γ[X][Y]). As shown in FIG. 21, only small values of the approximation errors (vectors γ[X][Y]) are biased in value, and the frequency distribution of the values is also biased in frequency. Therefore, data can be compressed by encoding the approximation errors (vectors γ[X¹] . . . [X^{L}]).

When the approximation errors (vectors γ[X¹] . . . [X^{L}]) are encoded, the encoding method is not particularly limited. For example, the approximation errors (vectors γ[X¹] . . . [X^{L}]) may be encoded by the above-described model approximation encoding of the linear combination, or the approximation errors (vectors γ[X¹] . . . [X^{L}]) may be encoded by entropy encoding represented by conventionally known Huffman coding.

The approximation model (vector Ea[X¹] . . . [X^{L}]) alone differs from the original error amount (vector E[X¹] . . . [X^{L}]) by the approximation errors (vectors γ[X¹] . . . [X^{L}]). Further, since the approximation errors (vector γ[X¹] . . . [X^{L}]) exist according to the number of pieces of data of each axis, if the approximation errors are held as they are, it is not possible to compress the data. However, if the approximation errors (vectors γ[X¹] . . . [X^{L}]) are encoded and combined with the approximation model (vector Ea[X¹] . . . [X^{L}]), the original error amount (vector E[X¹] . . . [X^{L}]) can be compressed and reproduced without loss, and the total data size can also be reduced.

According to the present embodiment, the following advantageous effects are achieved.

In the data encoding device 4 according to the present embodiment, the model approximation encoder 41 includes the approximation error calculator 42 that calculates an approximation error amount. The data encoding device 4 is configured to further include the approximation error encoder 43 that encodes the approximation error amount to generate an encoded approximation error amount. With such a configuration, according to the present embodiment, it is possible to encode and compress the axis-dependent data, which has been difficult to compress conventionally, and thus reproduce the axis-dependent data such as the original error amount without loss, while further reducing the total data size by encoding the approximation error amount.

### Fifth Embodiment

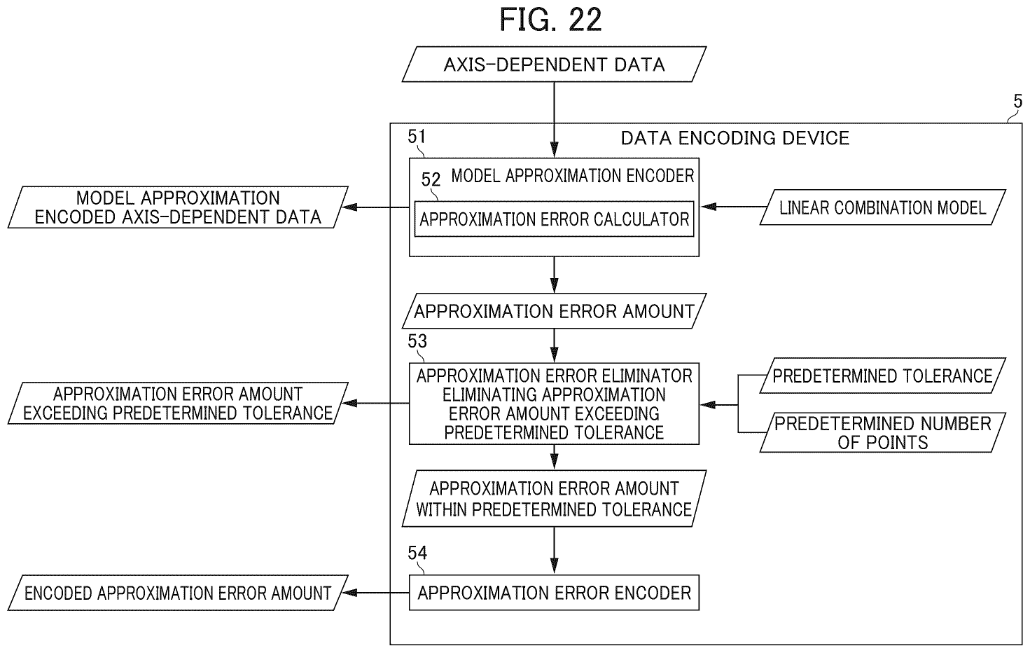

FIG. 22 is a diagram showing a configuration of a data encoding device 5 according to a fifth embodiment. As shown in FIG. 22, a data encoding device 5 according to the fifth embodiment differs from the data encoding device 4 according to the fourth embodiment in that the data encoding device 5 further includes an approximation error eliminator 53 that eliminates an approximation error amount equal to or greater than a predetermined tolerance. In addition, an approximation error encoder 54 differs from the approximation error encoder 43 according to the fourth embodiment in that the approximation error encoder 54 encodes an approximation error amount within a predetermined tolerance. The configurations other than these differences are the same as those of the fourth example.

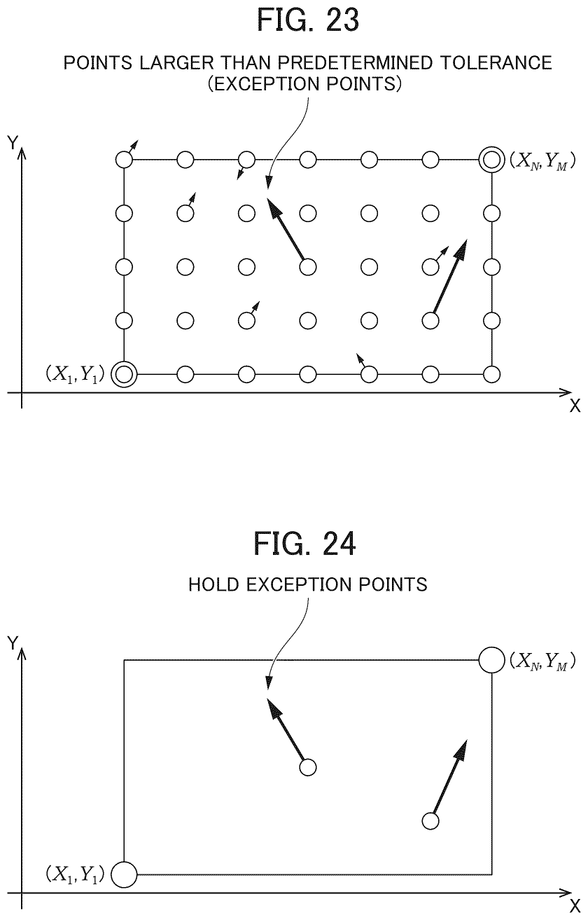

The approximation error eliminator 53 generates an approximation error amount within a predetermined tolerance by eliminating the approximation error amount exceeding a predetermined tolerance from the approximation error amount. Here, FIG. 23 is a diagram showing approximation errors (vectors γ[X][Y]), each including an exception point larger than a predetermined tolerance. As shown in FIG. 23, the approximation errors (vectors γ[X][Y]), which are each a difference between an original error amount before model approximation encoding and an error amount after model approximation encoding, may include an exception point larger than a predetermined tolerance. In the present embodiment, the exception points are eliminated by the approximation error eliminator 53.

FIG. 24 is a diagram showing exception points that are excluded and held because the approximation errors (vectors γ[X][Y]) are larger than a predetermined tolerance. As described above, the approximation error eliminator 53 may separately hold each of the exception points in which the approximation error is larger than a predetermined tolerance, that is, the approximation error amount exceeding a predetermined tolerance, which is eliminated from the approximation error amount. As a result, the axis-dependent data such as the original error amount can be compressed and reproduced without loss.

Examples of the predetermined tolerance include an approximation error allowable value and a predetermined number of points (allowable number of points) of data exceeding the approximation error allowable value. In this case, the approximation error eliminator 53 excludes a point exceeding a preset approximation error allowable value or a predetermined number of points among points exceeding the approximation error allowable value from the approximation errors (vectors γ[X][Y]). The predetermined tolerance may include 0.

The approximation error encoder 54 encodes an approximation error amount within a predetermined tolerance to generate an encoded approximation error amount. That is, when encoding the approximation errors (vectors γ[X¹] . . . [X^{L}]), the approximation error encoder 54 of the present embodiment performs encoding after excluding points at which the approximation error is larger than a predetermined tolerance.

The approximation error after excluding the points larger than the predetermined tolerance from the approximation error amount, that is, the approximation error amount within the predetermined tolerance, becomes more biased in value and the information entropy becomes smaller, so that the data compression effect is further enhanced by encoding. In addition, for example, the data size after encoding can be further reduced by holding the approximation error amount only at points at which the approximation error is larger than a predetermined tolerance and not holding the other approximation error amounts. Even in this case, it is possible to ensure that the entire approximation error falls within the tolerance.

According to the present embodiment, the following advantageous effects are achieved.

The data encoding device 5 according to the present embodiment further includes the approximation error eliminator 53 that generates an approximation error amount within a predetermined tolerance by eliminating an approximation error amount exceeding the predetermined tolerance from the approximation error amount. The approximation error encoder 54 is configured to encode an approximation error amount within a predetermined tolerance to generate an encoded approximation error amount. With such a configuration, according to the present embodiment, it is possible to encode and compress the axis-dependent data, which has been conventionally difficult to compress, and it is also possible to achieve compression with loss within the range of the allowable amount of loss (the predetermined tolerance and the predetermined number of points) by encoding the approximation error amount after the elimination of the approximation error amount exceeding the predetermined tolerance, and in this case, it is possible to reduce the data size compared to the compression without loss.

### Sixth Embodiment

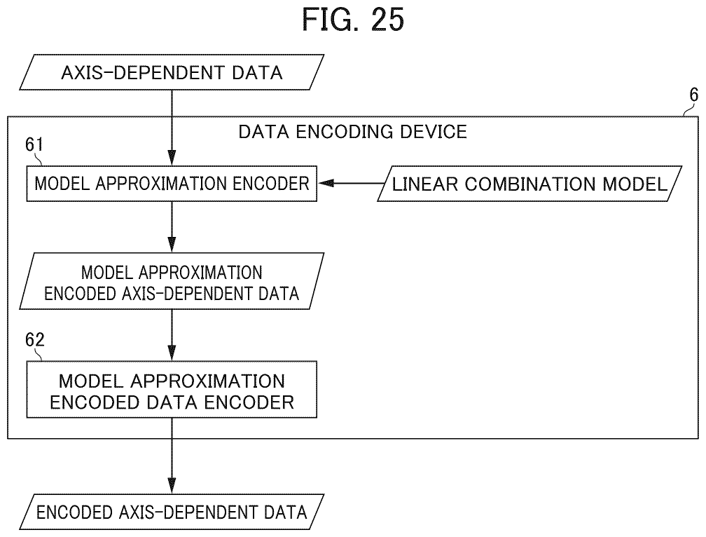

FIG. 25 is a diagram showing a configuration of a data encoding device 6 according to a sixth embodiment. As shown in FIG. 25, a data encoding device 6 according to the present embodiment differs from the data encoding device 1 described above in that the data encoding device 6 further includes a model approximation encoded data encoder 62. The configurations other than this difference are the same as those of the first example.

The model approximation encoded data encoder 62 encodes model approximation encoded axis-dependent data. That is, in the present embodiment, the model approximation encoded data encoder 62 performs re-encoding of the axis-dependent data after model approximation encoding.

As described in the above-mentioned first embodiment, when the error amount is expressed by the approximation model (vector Ea[X¹] . . . [X^{L}]) as the linear combination model represented by Expression (5), the data can be further compressed by performing encoding on each of the vectors Eaₓ¹[X]. At this time, since the vector Eaₓ¹[X¹] represents an error of each axis, the model approximation encoded data encoder 62 executes encoding by entropy encoding such as conventionally known Huffman coding, instead of model approximation by an approximation model (vector Ea[X¹] . . . [X^{L}]) as a linear combination model represented by the above-described Expression (5).

According to the present embodiment, the following advantageous effects are achieved.

The data encoding device 6 according to the present embodiment further includes the model approximation encoded data encoder 62 that encodes the encoded axis-dependent data. With such a configuration, according to the present embodiment, since the model approximation encoded data encoder 62 further encodes the encoded axis-dependent data, it is possible to further reduce the data size.

### Seventh Embodiment

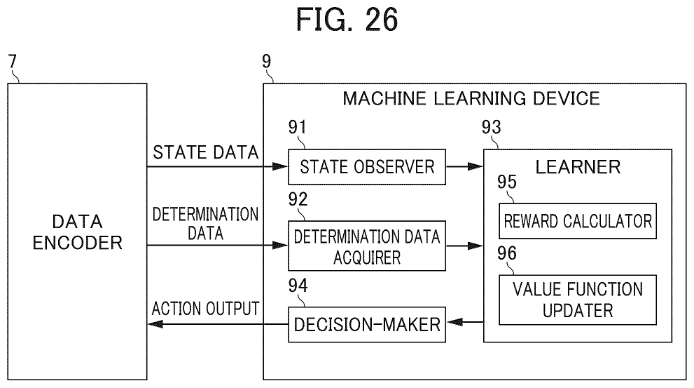

FIG. 26 is a diagram showing a configuration of a data encoding device 7 according to a seventh embodiment. As shown in FIG. 26, a data encoding device 7 according to the present embodiment differs from the data encoding device 3 according to the third embodiment in that the data encoding device 7 includes a learning result acquirer that acquires a reinforcement learning result by a machine learning device 9 instead of the dynamic programming method, and the axis-dependent data is divided into segments using the learning result. The configurations other than this difference are the same as those of the third embodiment.

The machine learning device 9 performs reinforcement learning for optimal division processing of axis-dependent data. In reinforcement learning by the machine learning device 9 according to the present embodiment, when the machine learning device 9 as an agent acquires axis-dependent data such as an error amount of an industrial machine as a state of an environment, and selects divided axis-dependent data as an action, the environment changes based on the action. As the environment changes, the number of points that cannot be approximated and the amount of data after approximation obtained by performing model approximation encoding on the divided axis-dependent data are obtained as determination data. Then, some reward is given according to the obtained determination data, and the machine learning device 9 as an agent selects a better action, i.e., learns the divided axis-dependent data optimal for decision making. The machine learning device 9 as an agent learns to select an action that maximizes the sum of rewards in the future.

Any learning method can be used for reinforcement learning. For example, Q learning, which is a method of learning a value Q(s, a) for selecting a certain action a under a certain state s of a certain environment, can be used. In the Q learning, in a certain state s, an action a having the highest value Q(s, a) is selected as an optimal action from among possible actions a. However, the correct value of the value Q(s, a) is not known at all for the combination of the state s and the action a at the time when the Q learning is started first. Therefore, the machine learning device 9 as an agent selects various actions a under a certain state s, and learns a correct value Q(s, a) by selecting a better action based on a reward given to the action a at that time.

In addition, in order to maximize the sum of rewards obtained in the future, the machine learning device 9 aims to finally obtain Q(s, a)=E[Σ(γ^{t})rₜ]. Here, E [ ] represents an expected value, t is a time, γ is a parameter of a discount rate to be described later, rₜ is a reward at the time t, and Z is a total at the time t. The expected value in this expression is an expected value when the state is changed according to the optimal action. However, since it is unknown what the optimal action is in the process of Q-learning, reinforcement learning is performed while searching for various actions. Such an update expression of the value Q(s, a) can be expressed by, for example, the following Expression (11).

$$\begin{matrix}[ Expression 11 ] & \\ Q ( {s}_{t + 1} , {a}_{t + 1} ) ← Q ( {s}_{t} , {a}_{t} ) + α ( {r}_{t + 1} + {γmax}_{a} Q ( {s}_{t + 1} , a ) - Q ( {s}_{t} , {a}_{t} ) ) & Expression ( 11 )\end{matrix}$$

In Expression (11), sₜ represents the state of the environment at time t, and at represents the action at time t. The state is changed to sₜ₊₁ by the action at. The term rₜ₊₁ represents a reward obtained by a change in the state. The term with max is obtained by multiplying, by γ, the Q value in a case where the action a having the highest Q value known at that time is selected under the state sₜ₊₁. Here, γ is a parameter of 0<γ≤1, and is referred to as a discount rate. Further, a is a learning coefficient, and is in a range of 0≤α≤1.

Expression (11) above represents a method of updating the value Q(sₜ, aₜ) of the action aₜ in the state sₜ based on the reward rₜ₊₁ returned as a result of the trial at. This update expression indicates that, if the value maxₐ Q(sₜ₊₁, a) of the best action in the next state sₜ₊₁ by the action at is larger than the value Q(sₜ, aₜ) of the action at in the state sₜ, Q(sₜ, aₜ) is increased, and if it is smaller, Q(sₜ, aₜ) is decreased. That is, the value of a certain action in a certain state is made closer to the value of the best action in the next state. However, although the difference varies depending on the discount rate γ and the reward rₜ₊₁, basically, the value of the best action in a certain state propagates to the value of the action in the immediately preceding state.

Here, in the Q learning, there is a method of creating a table of Q(s, a) for all the state action pairs (s, a) and performing learning. However, there is a case where the number of states is too large to obtain the values of Q(s, a) of all the state action pairs, and it would take a long time for the Q learning to converge.

Therefore, a known technique called Deep Q-Network (DQN) may be used. Specifically, the value function Q may be configured using an appropriate neural network, parameters of the neural network may be adjusted, and the value function Q may be approximated with an appropriate neural network, such that the value of the value Q(s, a) is calculated. By using the DQN, it is possible to shorten the time required for the Q-learning to converge. The DQN is described in detail in, for example, the Non-patent Document of “Human-level control through deep reinforcement learning”, Volodymyr Mnihl, [online], [searched on Jan. 17, 2017], the Internet <URL: http://files.davidqiu.com/research/nature14236.pdf>.

Therefore, in order to execute the reinforcement learning described above, the machine learning device 9 includes a state observer 91, a determination data acquirer 92, a learner 93, and a decision-maker 94, as shown in FIG. 26. The learner 93 includes a reward calculator 95 and a value function updater 96.

The state observer 91 acquires axis-dependent data as state data from the data encoding device 7. In addition, the state observer 91 outputs the acquired axis-dependent data to the learner 93.

The determination data acquirer 92 acquires, as determination data from the data encoding device 7, the number of points that cannot be approximated and the approximated data amount obtained by performing model approximation encoding on the divided axis-dependent data. The divided axis-dependent data is obtained by dividing the axis-dependent data into predetermined designated sections in accordance with a predetermined division criterion stored in advance. In addition, the determination data acquirer 92 outputs the acquired number of points that cannot be approximated and the approximated data amount to the learner 93.

The reward calculator 95 of the learner 93 calculates a reward based on the acquired axis-dependent data, the number of points that cannot be approximated and the approximated data amount. Specifically, the reward calculator 95 increases the reward when the number of points that cannot be approximated decreases, and decreases the reward when the number of points that cannot be approximated increases. In addition, the reward calculator 95 increases the reward when the approximated data amount decreases, and decreases the reward when the approximated data amount increases.

The value function updater 96 of the learner 93 updates the stored value function by performing the above-described Q learning based on the axis-dependent data as the state data, the number of points that cannot be approximated and the approximated data amount obtained by performing the model approximation encoding on the divided axis-dependent data as the determination data, and the value of the reward. In addition, the value function stored in the value function updater 96 can be shared by a plurality of machine learning devices communicably connected to each other, for example.

The decision-maker 94 acquires the updated value function from the value function updater 96. In addition, the decision-maker 94 outputs the optimal divided axis-dependent data as an action output to the data encoding device 7 based on the acquired value function.

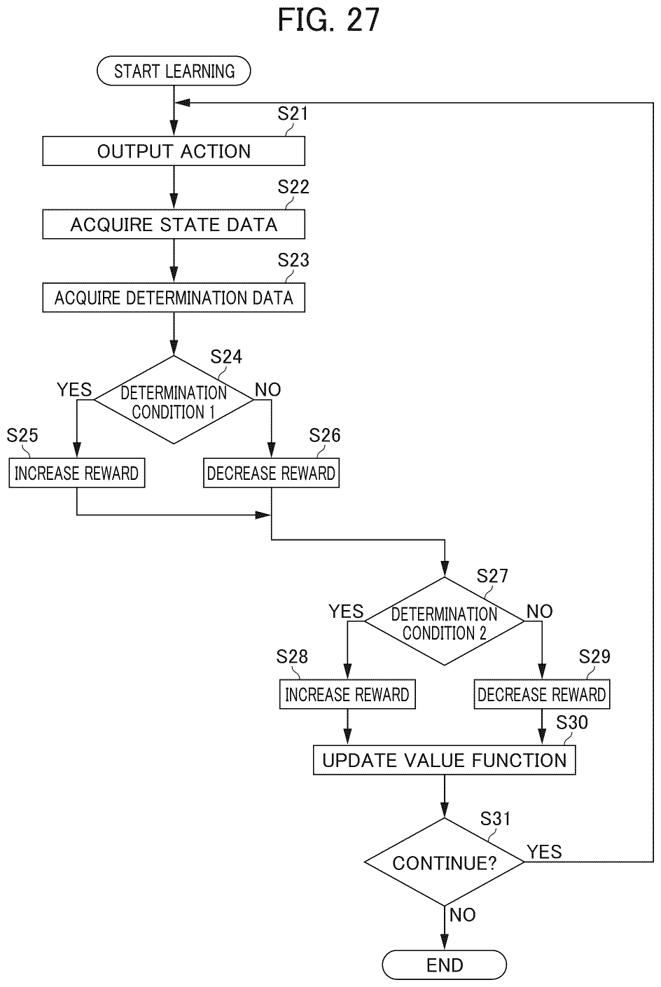

FIG. 27 is a flowchart showing a procedure of learning processing by the machine learning device 9.

In Step S21, first, the machine learning device 9 outputs the divided axis-dependent data as an action output to the data encoding device 7. The divided axis-dependent data outputted in this step is obtained by dividing the axis-dependent data into predetermined designated sections in accordance with a predetermined division criterion stored in advance. The data encoding device 7 performs model approximation encoding on the divided axis-dependent data to generate the number of points that cannot be approximated and the approximated data amount. Thereafter, the processing proceeds to Step S22.

In Step S22, the machine learning device 9 acquires axis-dependent data as state data from the data encoding device 7. Thereafter, the processing proceeds to Step S23.

In Step S23, the machine learning device 9 acquires, as determination data from the data encoding device 7, the number of points that cannot be approximated and the approximated data amount after model approximation encoding of the divided axis-dependent data generated in Step S21. Thereafter, the processing proceeds to Step S24.

In Step S24, as a determination condition 1, it is determined whether the number of points that cannot be approximated when the data encoding device 7 performs model approximation encoding on the divided axis-dependent data has decreased. If it is determined as YES, the processing proceeds to Step S25, where the reward is increased. On the other hand, if it is determined as NO, the processing proceeds to Step S26, where the reward is reduced. Thereafter, the processing proceeds to Step S27.

In Step S27, as a determination condition 2, it is determined whether the amount of data after the model approximation encoding when the model approximation encoding is performed on the divided axis-dependent data by the data encoding device 7 is decreased. If it is determined as YES, the processing proceeds to Step S28, where the reward is increased. On the other hand, if it is determined as NO, the processing proceeds to Step S29, where the reward is decreased. Thereafter, the processing proceeds to Step S30.

In Step S30, the value function stored in the value function updater 96 is updated. Specifically, the value function updater 96 updates the stored value function by performing the above-described Q-learning based on the axis-dependent data as the state data, the number of points that cannot be approximated and the approximated data amount obtained by performing the model approximation encoding on the divided axis-dependent data as the determination data, and the value of the reward. Thereafter, the processing proceeds to Step S31.

In Step S31, it is determined whether to continue the present learning process. If it is determined as YES, the processing returns to Step S21. On the other hand, if it is determined as NO, the present processing is ended.

According to the present embodiment, the following advantageous effects are achieved.

In the data encoding device 7 according to the present embodiment, the axis-dependent data divider is configured to generate optimal divided axis-dependent data based on the reinforcement learning result by the machine learning device 9. With such a configuration, according to the present embodiment, since the axis-dependent data can be divided into the optimal divided axis-dependent data that can be compressed while reducing the number pieces of data by the reinforcement learning by the machine learning device 9, it is possible to generate an optimal plurality of regions that can be regarded as the linear combination of data of each axis (each axis error), and by performing the model approximation encoding of the linear combination model for each region, it is possible to further compress the axis-dependent data, which has conventionally been difficult to compress.

In each embodiment of the data encoding device described above, a data encoding program for causing each data encoding device to execute each of pieces of processing may be provided. That is, as the first data encoding program, it is possible to provide a data encoding program for causing a computer to execute a model approximation encoding step of generating encoded axis-dependent data obtained by encoding axis-dependent data based on a portion of axis-dependent data depending on coordinate values of each axis of an industrial machine and a linear combination model approximating the axis-dependent data as a linear combination of data of each axis of the industrial machine.

Further, it is possible to provide a second data encoding program further including an axis-dependent data dividing step of dividing the axis-dependent data to generate a plurality of divided axis-dependent data in the first data encoding program, in which the model approximation encoding step generates the encoded axis-dependent data based on the plurality of divided axis-dependent data and the linear combination model.

Further, it is possible to provide a third data encoding program that further includes a dynamic programming processing step of generating the optimal encoded axis-dependent data by executing the dynamic programming method in the second data encoding program, and that causes a computer to execute an optimality evaluating step of evaluating the optimality of the encoded axis-dependent data, a partial dividing step of dividing the axis-dependent data into a plurality of portions to generate partial axis-dependent data, and an optimization result combining step of generating optimal divided axis-dependent data by expanding and combining the partial axis-dependent data.

Further, it is possible to provide a fourth data encoding program for causing a computer to execute the step of generating the optimal divided axis-dependent data based on the reinforcement learning result by the machine learning device in the second data encoding program.

Further, it is possible to provide a fifth data encoding program for causing a computer to execute an approximation error calculation step of calculating an approximation error amount and a step of encoding the approximation error amount to generate an encoded approximation error amount in the first to fourth data encoding programs.

Further, it is possible to provide a sixth data encoding program for causing a computer to execute a step of generating an approximation error amount within a predetermined tolerance by eliminating an approximation error amount exceeding the predetermined tolerance from the approximation error amount, and a step of generating an encoded approximation error amount by encoding the approximation error amount within the predetermined tolerance in the fifth data encoding program.

It is also possible to provide a seventh data encoding program for causing a computer to execute a step of encoding the encoded axis-dependent data in the first to sixth data encoding programs.

In addition, the present disclosure is not limited to the above-described embodiments, and modifications and improvements within a range in which the object of the present disclosure can be achieved are included in the present disclosure.

In the fourth embodiment described above, the model approximation encoder 41 is configured to include the approximation error calculator 42. However, for example, it may be configured to combine, by the data decoding device, the model approximation encoded axis-dependent data encoded by the data encoding device 4 and calculate the approximation error amount by the difference between the decoded axis-dependent data and the original axis-dependent data.

In addition, in the fourth embodiment described above, the configuration including the approximation error calculator 42 is applied to the first embodiment. However, the present invention is not limited thereto, and such a configuration may be applied to the second embodiment or the third embodiment. Further, in the above-described sixth embodiment, the configuration including the model approximation encoded data encoder 62 is applied to the first embodiment. However, the present invention is not limited thereto, and such a configuration can be applied to other embodiments. As described above, the above-described embodiments can be appropriately combined as long as their functions are not impaired.

In the seventh embodiment described above, the machine learning device 9 is provided separately from the data encoding device 7. However, the present invention is not limited thereto, and a machine learning device may be provided inside the data encoding device 7.

### EXPLANATION OF REFERENCE NUMERALS

1, 2, 3, 4, 5, 6, 7 data encoding device
9 machine learning device
11, 21, 31, 41, 51, 61 model approximation encoder
22, 32 axis-dependent data divider
33 dynamic programming processor
34 optimality evaluator after model approximation encoding (optimality evaluator)
35 partial divider of axis-dependent data (partial divider)
36 optimization result combiner of partial axis-dependent data (optimization result combiner)
42 approximation error calculator
43 approximation error encoder
52 approximation error calculator
53 approximation error eliminator eliminating approximation error exceeding the predetermined tolerance (approximation error eliminator)
54 approximation error encoder
62 model approximation encoded data encoder (encoded data encoder)

1. A data encoding device that encodes data, comprising:
a model approximation encoder that generates, based on a portion of axis-dependent data depending on coordinate values of each axis of an industrial machine, and a linear combination model that approximates the axis-dependent data as a linear combination of data of each axis of the industrial machine, encoded axis-dependent data obtained by encoding the axis-dependent data.

2. The data encoding device according to claim 1, further comprising an axis-dependent data divider that divides the axis-dependent data to generate a plurality of pieces of divided axis-dependent data,
wherein the model approximation encoder generates the encoded axis-dependent data based on the plurality of pieces of divided axis-dependent data and the linear combination model.

3. The data encoding device according to claim 2, wherein
the axis-dependent data divider includes a dynamic programming processor that executes dynamic programming to generate optimal divided axis-dependent data, and
the dynamic programming processor includes:
an optimality evaluator that evaluates optimality of the encoded axis-dependent data;
a partial divider that divides the axis-dependent data into a plurality of portions to generate partial axis-dependent data; and
an optimization result combiner that expands and combines the partial axis-dependent data to generate optimal divided axis-dependent data.

4. The data encoding device according to claim 2, wherein the axis-dependent data divider generates optimal divided axis-dependent data based on a reinforcement learning result by a machine learning device.

5. The data encoding device according to claim 1, wherein
the model approximation encoder includes an approximation error calculator that calculates an approximation error amount, and
the data encoding device further includes an approximation error encoder that encodes the approximation error amount to generate an encoded approximation error amount.

6. The data encoding device according to claim 5, further comprising an approximation error eliminator that eliminates an approximation error amount exceeding a predetermined tolerance from the approximation error amount, thereby generating an approximation error amount within the predetermined tolerance,
wherein the approximation error encoder encodes an approximation error amount within the predetermined tolerance to generate the encoded approximation error amount.

7. The data encoding device according to claim 1, further comprising an encoded data encoder that encodes the encoded axis-dependent data.

8. A non-transitory computer-readable medium storing a data encoding program that encodes data, the non-transitory computer-readable medium storing the data encoding program causing a computer to execute
a step of generating, based on a portion of axis-dependent data depending on coordinate values of each axis of an industrial machine, and a linear combination model that approximates the axis-dependent data as a linear combination of data of each axis of the industrial machine, encoded axis-dependent data obtained by encoding the axis-dependent data.
